(19) United States
(12) Patent Application Publication
(10) Pub. No.: US 2026/0123055 A1
(43) Pub. Date: Apr. 30, 2026

(54) LAYOUT AND STRUCTURE OF PROTECTION DIODE CIRCUIT FOR 3D IC

(71) Applicant: UNITED MICROELECTRONICS CORP., Hsin-Chu City (TW)

(72) Inventors: Chin-Wei Ho, Tainan City (TW); Chee Hau Ng, Singapore (SG); Tsung-Ying Tsai, Kaohsiung City (TW); Ji Feng, Singapore (SG); Guohai Zhang, Singapore (SG)

(73) Assignee: UNITED MICROELECTRONICS CORP., Hsin-Chu City (TW)

(21) Appl. No.: 18/986,712

(22) Filed: Dec. 19, 2024

(30) Foreign Application Priority Data
Oct. 25, 2024 (TW) 113140680

(51) Int. Cl. H10D 89/60; H01L 25/065; H10D 80/30

(52) U.S. Cl. CPC H10D 89/611; H10D 80/30; H10W 90/00

(57) ABSTRACT

A protection diode circuit for 3D IC is provided in the present invention, including a SOI substrate, a BEOL metal interconnect on the SOI substrate, a bottom contact connecting a silicon base of the SOI substrate and a first part of the BEOL metal interconnect, a first protection diode with a first gate connecting the first part, a first P-type doped region connecting the first part and a first N-type doped region connecting a second part of the SOI substrate, a second protection diode with a second gate connecting the second part, a second P-type doped region connecting the second part, and a second N-type doped region connecting a third part of the BEOL metal interconnect.

### BACKGROUND OF THE INVENTION

### 1. FIELD OF THE INVENTION

The present invention generally relates to a layout and a structure of protection diode circuit, and more specifically, to a layout and a structure of protection diode circuit for 3D IC.

### 2. DESCRIPTION OF THE PRIOR ART

Three-dimensional integrated circuit (3D IC) is next generation technology. By stacking and bonding multiple IC dies in the vertical direction and establishing electrical connection through advanced interconnects (such as μ-bumps or through-silicon via TSV), this structure can increase the integration of devices per unit area in a chip, shortening signal transmission path to reduce delay and power consumption, and various circuits and/or devices with different functions (such as logic, storage and radio frequency (RF)) may be integrated in the same chip to improve system performance. Due to the advantages above, 3D IC can be applied in many fields, such as memories like DRAM and FLASH, processors like CPU and GPU, communication equipment like RF and 5G components, and consumer electronics with multi-functional modules.

Among them, in terms of communication equipment, the rapid development of 5G communication technology in recent years has increase the use of RF front-end components year by year, driving the market demand of RF-SOI (Radio Frequency Silicon-On-Insulator) components. RF-SOI is a silicon-based material technology designed specifically for RF applications. This technology uses SOI structure to place a thin silicon piece on an insulating layer. Compared with ordinary silicon substrates, it can effectively reduce leakage current and improve power efficiency, especially suitable for RF equipment that requires long-term operation, and its good high-frequency characteristics enable the chip to operate stably in the frequency range of several GHz, making it suitable for the applications like wireless communication and radar. Cooperating with 3D IC technology, RF-SOI components can be highly integrated with digital circuits and other analog circuits, simplifying system design and reducing costs.

However, since 3D IC is integrated by multiple dies, and different dies have different inherent potentials, which makes the components susceptible to the influence of other dies and changes their electrical properties, such as threshold voltage shift, and components are also easily damaged by electrostatic discharge during high-frequency operation, affecting the reliability and performance of the device. Accordingly, those of skilled in the art need to design a circuit structure for protecting 3D IC to avoid the aforementioned problems.

### SUMMARY OF THE INVENTION

In view of the aforementioned problems encountered in conventional skills, the present invention hereby proposes a novel layout and structure for protection diode circuit, which can be used to protect the components in 3D ICs, as well as compatible with existing RF-SOI process.

One aspect of the present invention is to provide a layout of protection diode circuit for a 3D IC, including: a SOI substrate consisting of a silicon substrate, a buried oxide layer and a silicon layer; a BEOL metal interconnect on the SOI substrate; a bottom contact penetrating the silicon layer and the buried oxide layer and electrically connecting the silicon substrate and a first part of the BEOL metal interconnect; a first protection diode includes: a first gate on the silicon layer and connected to the first part of the BEOL metal interconnect; a first P-type doped region in the silicon layer at one side of the first gate and connected to the first part; and a first N-type doped region in the silicon layer at the other side of the gate and connected to a second part of the BEOL interconnect; a second protection diode includes: a second gate on the silicon layer and connected to the second part of the BEOL metal interconnect; a second P-type doped region in the silicon layer at one side of the second gate and connected to the second part; and a second N-type doped region in the silicon layer at the other side of the gate and connected to a third part of the BEOL interconnect.

Another aspect of the present invention is to provide a structure of protection diode circuit for 3D IC, including: a first die with a SOI substrate consisting of a silicon substrate, a buried oxide layer and a silicon layer; a BEOL metal interconnect on the SOI substrate; a bottom contact penetrating the silicon layer and the buried oxide layer and connecting the silicon substrate and a first part of the BEOL interconnect; a first protection diode, including: a first gate on the silicon layer and connected to the first part of the BEOL metal interconnect; a first P-type doped region in the silicon layer at one side of the gate and connected to the first part; and a first N-type doped region in the silicon layer at the other side of the gate and connected to a second part of the BEOL metal interconnect; a second protection diode, including: a second gates on the silicon layer and connected to the second part of the BEOL metal interconnect; a second P-type doped region in the silicon layer at one side of the second gate and connected to the second part; and a second N-type doped region in the silicon layer at the other side of the gate and connected to a third part of the BEOL metal interconnect; a second die with a semiconductor device, wherein the first die is directly connected with the second die through the BEOL metal interconnect to form a 3D IC chip, and the semiconductor device is connected with the BEOL metal interconnect.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view of a 3D IC in accordance with one embodiment of the present invention;

FIG. 2 is a schematic layout of protection diode circuit for 3D IC in accordance with one embodiment of the present invention; and

FIG. 3 is a schematic cross-sectional view of protection diode circuit for 3D IC in accordance with one embodiment of the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). Further, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein in the description of the invention, the “N” and “P” designations, as in “N type” and “P type”, are used in the common manner to designate donor and acceptor type impurities which promote electron and hole type carriers respectively as the majority carriers. The “++” symbol, when used as a suffix with an impurity type should be interpreted to mean that the doping concentration of that impurity is heavier than the doping associated with just the letter identifying the impurity type without the “+” suffix. Conversely, the “−” symbol, when used as a suffix with an impurity type should be interpreted that the doping concentration of that impurity is lighter than the doping associated with just the letter identifying the impurity type without the “−”suffix.

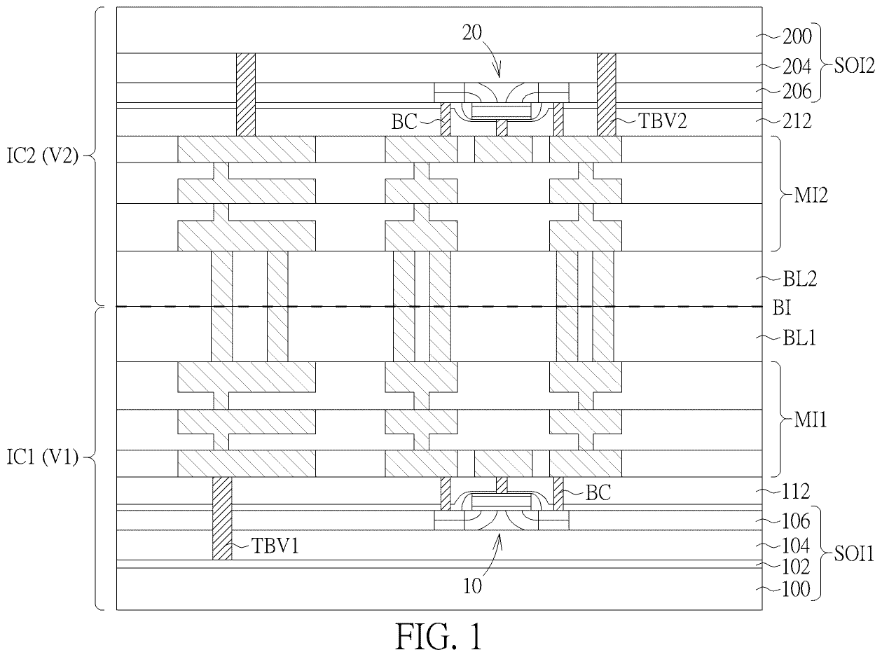

First, please refer to FIG. 1, which is a schematic cross-sectional view of a 3D IC according to one embodiment of the present invention. As shown in the figure, the 3D IC of the present invention may be formed by bonding a first die IC1 and a second die IC2. In the embodiment of the present invention, the first die IC1 and the second die IC2 may be RFIC, wherein CMOS devices and various RF components may be disposed therein, such as amplifiers, switches and/or filters in RF front-end module, but is not limited thereto. Each die in the figure is shown with only one device for representative purposes. The first die IC1 uses a SOI substrate SOI1 as the basis for components to be formed thereon, wherein the SOI substrate SOI1 may be composed of a silicon substrate 100, a buried oxide layer 104 and a thin silicon layer 106. The silicon substrate 100 functions as a bulk silicon for SOI substrate SOI1, with a relatively larger thickness of approximately 500 μm to 1000 μm. The buried oxide layer 104 is located above the silicon substrate 100 and may be made of silicon oxide with a thickness of about 100 nm to 400 nm. The buried oxide layer 104 can electrically isolate the silicon substrate 100 from the thin silicon layer 106 above to reduce leakage current, thereby improving device performance and reliability. In the embodiment, a trap-rich layer 102 may be provided between the buried oxide layer 104 and the silicon substrate 100. The trap-rich layer 102 may be made of silicon nitride with a thickness of about 10 nm to 100 nm. The trap-rich layer 102 can capture free carriers, reducing the carrier concentration in the silicon layer to further increase the resistance of the SOI substrate, making it particularly suitable for high-frequency or high-voltage applications. The thin silicon layer 106 is a device layer, in which various doped regions required by the devices will be formed. Its material can be P-type doped silicon with a thickness of about 50 nm to 200 nm.

Refer still to FIG. 1. In the embodiment, a first device 10 is formed on the SOI substrate SOI1, such as a metal oxide semiconductor field effect transistor (MOSFET), with its source/drain formed in the thin silicon layer 106 of the SOI substrate SOI1, while the gate is disposed on the surface of the thin silicon layer 106. These terminals can be electrically connected to the upper BEOL metal interconnect MI1 through the contacts BC formed in an interlayer dielectric layer (ILD) 112. Furthermore, in the embodiment, the trap-rich layer 102 in the SOI substrate SOI1 may also be electrically connected to the BEOL metal interconnect MI1 through a bottom contact TBV1 to conduct the trap-rich layer 102 to an external circuit, such as a high-frequency capacitor on the other side. The BEOL metal interconnect MI1 is composed of multiple metal layers and vertically connected vias, which are formed in corresponding inter-metal dielectric layers (IMDs) and can electrically connect different devices and components to ensure that signals and power can be transmitted throughout the circuit.

Refer still to FIG. 1. In the embodiment, the structure of second die IC2 is much the same as the first die IC1, with only difference that it is not provided with a trap-rich layer. As shown in the figure, the second die IC2 uses a SOI substrate SOI2 as the basis for the components to be formed thereon, wherein the SOI substrate SOI2 may be composed of a silicon substrate 200, a buried oxide layer 204 and a thin silicon layer 206. A second device 20 is formed on the SOI substrate SOI2, and its terminals can be electrically connected to BEOL metal interconnects MI2 through contacts BC formed in an ILD layer 212. Furthermore, the silicon substrate 200 in the SOI substrate SOI2 can also be electrically connected to the BEOL metal interconnect MI2 through a bottom contact TBV2, so as to be further connected to external RF components in later process, such as high-frequency capacitor. In the embodiment, the second die IC2 is stacked on the first die IC1, and the two wafers are bonded by abutting their uppermost bonding layers BL1, BL2, wherein the BI in the figure is the bonding interface. Furthermore, the hybrid vias HBV1, HBV2 in the bonding layers BL1, BL2 will also be jointed with each other during this process to achieve a circuit connection between the two dies, so as to construct a 3D IC architecture.

In practice, after the first die IC1 and the second die IC2 are bonded, the silicon substrate 200 on the back side of the second die IC2 can be removed to expose the bottom contact TBV2 that penetrates the thin silicon layer 206 and the buried oxide layer 204, and a post-bonding process of the 3D IC will be continued thereon, such as manufacturing the MIM (metal-insulator-metal) high-frequency capacitors for RF ICs, metal layers and ultra-thick metals (UTM) for inductors and external pads, etc. Since these components are not the focus of the present invention, they will not be described in detail here.

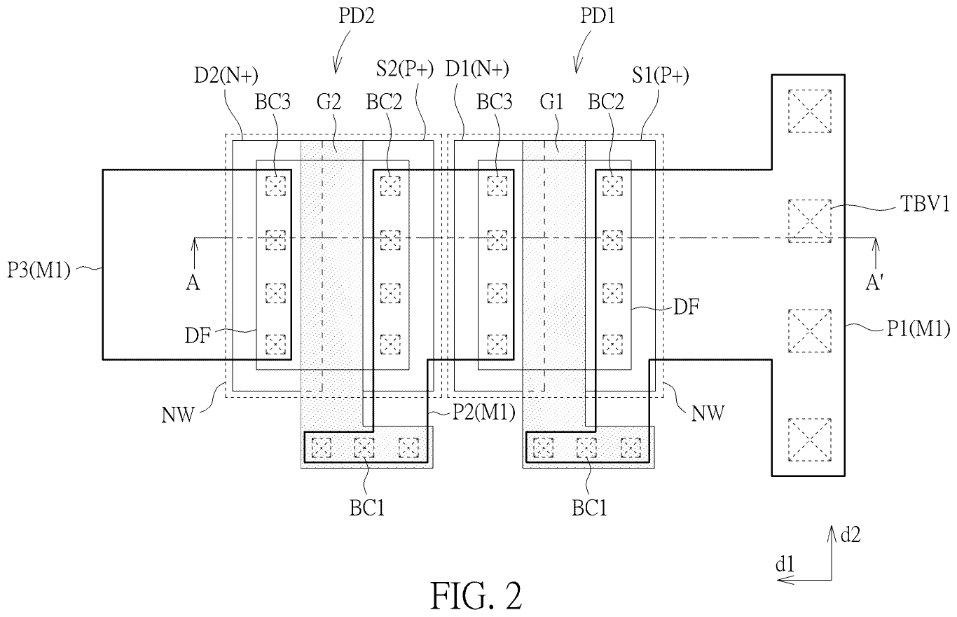

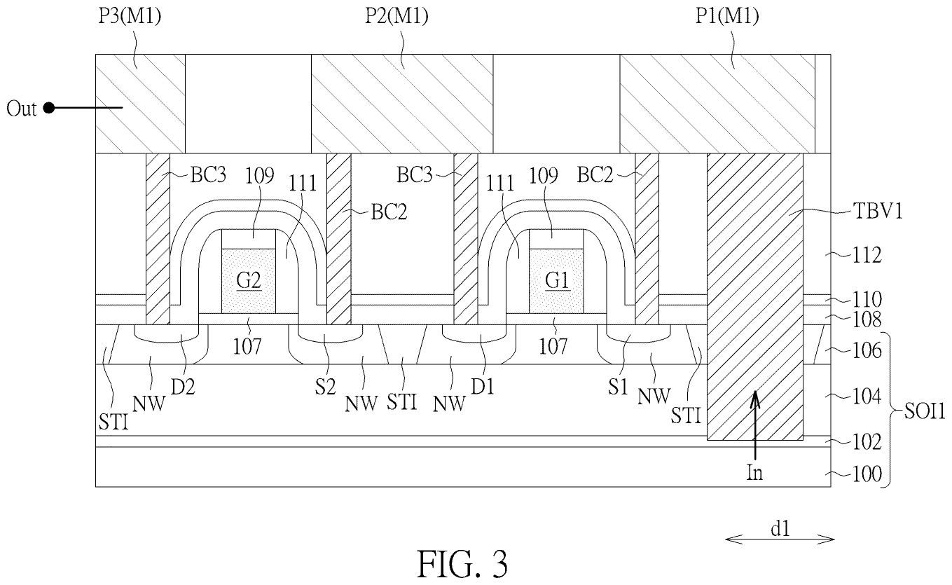

In the present invention, since the first die IC1 and the second wafer IC2 have different inherent potentials V1, V2, the potential difference between the two dies after bonding may easily cause the carriers in the trap-rich layer 102 of the first die IC1 flowing to the second device 20 in the second die IC2 through the connecting BEOL metal interconnects MI1, MI2, shifting the threshold voltage of second device 20, and in severe cases, even causing damage to the device. According, the present invention proposes a protection diode circuit to solve this problem. In following embodiments, the layout and structure of the protection diode circuit will be described with reference to FIGS. 2 and 3.

Please refer now to FIG. 2, which is a schematic layout diagram of a protection diode circuit for 3D IC in accordance with an embodiment of the present invention. The protection diode circuit of the present invention consists mainly of two series-connected protection diodes. As shown in the figure, in the embodiment, each protection diode PD1, PD2 is composed of a gate G1, G2, a P-type doped region S1, S2 (i.e., the anode of the diode) and an N-type doped regions D1, D2 (i.e., the cathode of the diode), wherein the P-type doped regions S1, S2 and the N-type doped regions D1, D2 may be heavily doped regions formed in the aforementioned thin silicon layer 106 (FIG. 1). The two heavily doped regions have different doping types (P+, N+) to form a diode. Gates G1 and G2 serve as isolation structures between the anode and cathode of the diode. They may be polysilicon layer formed on the thin silicon layer 106 and abutting the P-type doped regions S1, S2 and the N-type doped regions at both sides. In terms of shape, the gates G1, G2, the P-type doped regions S1, S2 and the N-type doped regions D1, D2 may be in a strip shape extending in a second direction d2. The second direction d2 is preferably perpendicular to the first direction d1. In practice, a shallow trench isolation (STI, see FIG. 3) is first formed in the thin silicon layer 106 to define the diffusion regions DF (also called an active area, AA) for every device, which serves as the conductive regions of the device. Thereafter, N-type dopants such as phosphorus (P) and arsenic (As) are doped into the defined N-well region NW through ion implantation or diffusion process, so that N-well may be formed in silicon-based diffusion regions DF. The P-type doped regions S1, S2 and the N-type doped regions D1, D2 can also be doped through the same doping process, using the gates G1, G2 as masks to dope the exposed diffusion regions DF, so that they may be formed self-alignedly on the N-well of the diffusion regions. It should be noted that various doped regions shown in the figure are mask patterns. The dimension and range of the doped regions formed in the actual process will depend on the mask presented during the process and the substrate to be doped.

Refer still to FIG. 2. The protection diodes PD1, PD2 are preferably adjacent to one another in the first direction d1, and the N-type doped region D1 of the protection diode PD1 will be adjacent to the P-type doped region S2 of the protection diode PD2, so as to facilitate the connection to BEOL circuits. In the embodiment, every terminal of the protection diodes PD1, PD2 is connected to BEOL metal interconnect and/or external circuit through corresponding contact. Specifically, in the embodiment of present invention, the trap-rich layer 102 in the first die IC1 is connected to the upper BEOL metal interconnect MI1 (FIG. 1) through a bottom via TBV1 penetrating layer structures like the buried oxide layer 104, thin silicon layer 106 and the ILD layer 112. The bottom contacts TBV1 may be aligned in the second direction d2, and what they are connected to may be a first part P1 of the first metal layer M1 in the BEOL metal interconnect. The P-type doped region S1 of protection diodes PD1 may also be connected upwardly to the first part P1 through contact BC2. In addition, the gate G1 of protection diode PD1 is also connected upwardly to the first part P1 through the contact BC1. On the other hand, the N-type doped region D1 of the protection diode PD1 is connected upwardly to a second part P2 of the first metal layer M1 through the contact BC3, and the gate G2 of protection diode PD2 and the P-type doped region S2 is also connected upwardly to the second part P2 through contacts BC1 and BC2 respectively. The contact BC1 may be aligned in the first direction d1, the contact BC2 may be aligned in the second direction d2, and the contact BC3 may be aligned in the second direction d2. In this way, the protection diode PD1 and the protection diode PD2 are connected in series through the second part P2 of the first metal layer M1. On the other hand, the N-type doped region D2 of the protection diode PD2 is connected upwardly to a third part P3 of the first metal layer M1 through the contact BC3, and is further connected to subsequent circuit of the 3D IC through the third part P3, such as the devices to be protected.

Please refer to FIG. 3, which is a schematic cross-sectional view of the aforementioned protection diode circuit taken along the section line A-A′ in FIG. 2. The following embodiments will illustrate the structure of the protection diode circuit from the perspective of this cross-section in the present invention. As shown in the figure, the protection diodes PD1, PD2 of the present invention are preferably formed on the SOI substrate SOI1 of the first die IC1 (FIG. 1). At the beginning of the circuit, the trap-rich layer 102 and/or silicon substrate 100 in the SOI substrate SOI1 is first connected to a first part P1 of the first metal layer M1 through a bottom contact TBV1, which penetrates through layer structures like the buried oxide layer 104, shallow trench isolation STI, buffer layer 108, etch stop layer 110 and the ILD layer 112. The protection diodes PD1 and PD2 can be disposed on the diffusion area (i.e., the thin silicon layer 106 in this figure) near the bottom contact TBV1, which is surrounded and defined by the shallow trench isolation STI, in which the P-type doped regions S1, S2 and the N-type doped regions D1, D2 of the protection diodes PD1, PD2 can be formed in the N-well NW defined in the thin silicon layer 106, while the isolation gates G1 and G2 of the protection diodes PD1 and PD2 are disposed on the thin silicon layer 106 between the P-type doped regions S1, S2 and N-type doped regions D1, D2, with a gate oxide layer 107 isolating between the thin silicon layer 106 and the isolation gates G1, G2 to further improve electrical isolation. A hard mask layer 109 and spacers 111 are further formed on the top and both sides of the gates G1, G2 to facilitate the patterning and definition of the P-type doped regions S1, S2 and the N-type doped regions D1, D2.

Refer still to FIG. 3, in the embodiment, the first part P1 of the first metal layer M1 will be connected downwardly to the P-type doped region S1 of the protection diode PD1 through contact BC2, and the N-type doped region D1 at the other end of the protection diode PD1 is connected upwardly to the second part P2 of the first metal layer M1 through a contact BC3. Similarly, the second part P2 will be connected downwardly to the P-type doped region S2 of the protection diode PD2 through contact BC2, and the N-type doped region D2 at the other end of the protection diode PD2 will be connected upwardly to the third part P3 of the first metal layer M1 through the contact BC3, and is further connected to the subsequent circuit of the 3D IC through the third part P3.

According to the circuit design described in the aforementioned embodiment, in actual operation, the protection diodes PD1 and PD2 can protect the MOS devices in main circuit through gate clamping mechanism. The trap-rich layer 102 of the first die IC1 (i.e., the input terminal In), which has high carrier concentration and is prone to generate electrostatic surges, is connected to the P-type doped region S1 (i.e. anode) and gate G1 of the protection diode PD1 through the bottom contact TBV1 and the first part P1 of BEOL metal layer, and achieve a series-connection of the two protection diodes PD1, PD2 through the BEOL metal layer. The polysilicon-based gates G1, G2 can provide better isolation effect in the string of the protection diodes PD1, PD2 to provide better current carrying capacity and less on-resistance and turn-on time. The N-type doped region D2 (i.e., cathode) of the protection diode PD2 will be connected with the source or drain of the circuit or MOS device (such as the second device 20 in the second die IC2) to be protected through the third part P3 (i.e., the output terminal Out) of the BEOL metal layer. The protection diodes PD1, PD2 are adjusted to be closed under normal operation condition and will be opened when an electrostatic surge occurs, with an open circuit voltage greater than an absolute voltage value but less than the breakdown voltage of the device to be protected. This can effectively clamp the voltage of the trap-rich layer 102 from exceeding its breakdown voltage, avoiding damage or threshold voltage shift of the device, which is the effectiveness of the present invention in fact. By connecting the two protection diodes in series, the present invention can further reduce the impact of the trap-rich layer to other circuits through the thick gate oxide layer and the polysilicon-based gate therein, which is one of the advantages of the present invention. The aforementioned protection diode circuit is compatible with currently existing RF-SOI process and can be integrated with the first device 10 in the manufacturing process of the first die IC1, thereby saving the required costs and process steps, which is another advantage of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A layout of protection diode circuit for 3D IC, comprising:
a SOI substrate composed of a silicon substrate, a buried oxide layer and a silicon layer;
a BEOL metal interconnect on said SOI substrate;
a bottom contact penetrating said silicon layer and said buried oxide layer and electrically connecting said silicon substrate and a first part of said BEOL metal interconnect;
a first protection diode, comprising:
a first gate on said silicon layer and connected to said first part of said BEOL metal interconnect;
a first P-type doped region in said silicon layer at one side of said first gate and connected to said first part; and
a first N-type doped region in said silicon layer at the other side of said first gate and connected to a second part of said BEOL metal interconnect;
a second protection diode, comprising:
a second gate on said silicon layer and connected to said second part of said BEOL metal interconnect;
a second P-type doped region in said silicon layer at one side of said second gate and connected to said second part; and
a second N-type doped region in said silicon layer at the other side of the second gate and connected to a third part of said BEOL metal interconnect.

2. The layout of protection diode circuit for 3D IC of claim 1, wherein said first P-type doped region of said first protection diode is adjacent to said second P-type doped region of said second protection diode in a first direction, and said first P-type doped region, said second P-type doped region, said first N-type doped region, said second N-type doped region, said first gate and said second gate extend in a second direction.

3. The layout of protection diode circuit for 3D IC of claim 2, wherein said bottom contacts are aligned in said second direction.

4. The layout of protection diode circuit for 3D IC of claim 2, wherein said first gate and said second gate are respectively connected to said first part and said second part through first contacts, and said first contacts are aligned in said first direction.

5. The layout of protection diode circuit for 3D IC of claim 2, wherein said first P-type doped region and said second P-type doped region are respectively connected to said first part and said second part through second contacts, and said second contacts are aligned in said second direction.

6. The layout of protection diode circuit for 3D IC of claim 2, wherein said first N-type doped region and said second N-type doped region are respectively connected to said second part and said third part through third contacts, and said third contacts are aligned in said second direction.

7. The layout of protection diode circuit for 3D IC of claim 1, wherein said first part, said second part and said third part of said BEOL metal interconnect are in said first metal layer.

8. A structure of protection diode circuit for 3D IC, comprising:
a first die, comprising:
a SOI substrate composed of a silicon substrate, a buried oxide layer and a silicon layer;
a BEOL metal interconnect on said SOI substrate;
a bottom contact penetrating said silicon layer and said buried oxide layer and electrically connecting said silicon substrate and a first part of said BEOL metal interconnect;
a first protection diode, comprising:
a first gate on said silicon layer and connected to said first part of said BEOL metal interconnect;
a first P-type doped region in said silicon layer at one side of said first gate and connected to said first part; and
a first N-type doped region in said silicon layer at the other side of said first gate and connected to a second part of said BEOL metal interconnect;
a second protection diode, comprising:
a second gate on said silicon layer and connected to said second part of said BEOL metal interconnect;
a second P-type doped region in said silicon layer at one side of said second gate and connected to said second part; and
a second N-type doped region in said silicon layer at the other side of said second gate and connected to a third part of said BEOL metal interconnect; and
a second die with a semiconductor device, wherein said first die is directly connected with said second die through said BEOL metal interconnect to form a 3D IC, and said semiconductor device are connected with said BEOL metal interconnect.

9. The structure of protection diode circuit for 3D IC of claim 8, further comprising a trap-rich layer between said silicon substrate and said buried oxide layer, and said bottom contact is connected with said trap-rich layer and said first part of said BEOL metal interconnect.

10. The structure of protection diode circuit for 3D IC of claim 8, wherein said second die comprises another SOI substrate, and said second die is connected with said BEOL metal interconnect of said first die through another BEOL metal interconnect to form said 3D IC.

11. The structure of protection diode circuit for 3D IC of claim 10, wherein said bottom contact in said first die is connected to said semiconductor device in said second die through said BEOL metal interconnect and said another BEOL metal interconnect.

12. The structure of protection diode circuit for 3D IC of claim 8, further comprising N-wells in said silicon layer, and said first P-type doped region, said second P-type doped region, said first N-type doped region and said second N-type doped region are in said N-wells.

13. The structure of protection diode circuit for 3D IC of claim 8, wherein said first part, said second part and said third part of said BEOL metal interconnect are in said first metal layer.
